(19) United States
(12) Patent Application Publication
(10) Pub. No.: US 2004/0145389 A1
(43) Pub. Date: Jul. 29, 2004

(54) High speed current mode NOR logic circuit

(75) Inventor: Hung-Chang Yu, Taipei (TW)

Correspondence Address: STEPHEN B. ACKERMAN, 28 DAVIS AVENUE, POUGHKEEPSIE, NY, 12603, US

(73) Assignee: Taiwan Semiconductor Manufacturing Company

(21) Appl. No.: 10/353,111

(22) Filed: Jan. 28, 2003

(51) Int. Cl. H03K 19/20

(52) U.S. Cl. 326/115

(57) ABSTRACT

This invention provides a circuit and a method for producing a high speed CMOS NOR circuit. The high speed CMOS current mode NOR circuit of this invention is further used to produce other high speed, low power circuits. This invention uses current mode logic in conjunction with complementary metal oxide semiconductor CMOS circuit technology. The invention uses a small signal differential amplifier technique to create high speed circuits with low power dissipation.

### BACKGROUND OF THE INVENTION

1. Field of the Invention

This invention relates to a circuit and a method for producing a high speed complementary metal oxide semiconductor CMOS phase detector. More particularly this invention relates to a circuit and a method which uses a current mode NOR logic circuit in order to provide a phase detector with high speed and low power dissipation.

2. Description of Related Art

FIG. 1 illustrates a conventional two input NOR circuit implemented with complementary metal oxide semiconductor CMOS technology. The two logic inputs are Vx 150 and Vy 160. These two logic inputs drive the gates of two parallel NMOS (N metal oxide semiconductor) field effect transistors FETs 130, 140. The N refers to N type semiconductor conductivity. The sources of these NMOS devices are attached to ground 180. The drains of these NMOS devices attached to node 135. The two logic inputs also drive two serial PMOS FETs where P refers to P type semiconductor conductivity.

Below is the standard NOR Truth table. In FIG. 1, when Vx 150 and Vy 160 are both logical ‘1’ or either signal is a logical ‘1’, the Vout node 135 is discharged to a logical ‘0’. This is also shown in the truth table below. If both Vx 150 and Vy 160 are logical ‘0’, then the Output node 135 remains high. This occurs since the discharging FETs 130, 140 are ‘off’ and the charging FETs 110, 120 are ‘on’.

| Input | Input | Output |
|---|---|---|
| Vx | Vy | Vout |
| 0 | 0 | 1 |
| 0 | 1 | 0 |
| 1 | 0 | 0 |
| 1 | 1 | 0 |

U.S. Pat. No. 5,889,430 (Csanky) “Current Mode Transistor Circuit” describes the formation of a current-mode CMOS NOR gate that lacks the current bias transistor and the load resistors. The circuit uses a low current mirror load in a logic circuit designed for low power operation. In addition, the circuit is designed to be insensitive to external radiation.

U.S. Pat. No. 6,104,214 (Ueda et al.) “Current Mode Logic Circuit, Source Follower Circuit, and Flip Flop Circuit” discloses a current-mode logic circuit. The body terminals and the gates of the NMOS devices are connected together to control the body bias. The circuit operates at low voltage and at a high speed. This invention also provides a high speed source follower circuit and a high speed flip flop circuit.

U.S. Pat. No. 5,550,491 (Furuta) “Current Mode Logic Circuit” shows a current-mode logic circuit. A differential pair is used to improve immunity to noise and power source fluctuation. The differential pair is cross-coupled and a bias transistor is not used.

### BRIEF SUMMARY OF THE INVENTION

It is the objective of this invention to produce a high speed current mode NOR logic circuit.

It is further an object of this invention to produce a high speed current mode NOR logic circuit with low power dissipation.

The objects of this invention are achieved by a high speed, low power complementary metal oxide semiconductor CMOS current mode NOR circuit made up of a current source connected between said internal node and ground, a differential pair of field effect transistors FETs connected in parallel with common source and drain terminals between said second internal node and said first internal node, a bias FET connected between said first internal node and said third internal node, said first load resistor connected between said second internal node and the power supply voltage and said second load resistor connected between said third internal node and the power supply voltage.

### BRIEF DESCRIPTION OF THE DRAWINGS

FIG. 1 shows a prior art conventional two input CMOS NOR circuit.

FIG. 2 shows a general schematic of the CMOS NOR circuit of this invention.

FIG. 3 shows a more detailed schematic of the CMOS NOR circuit of this invention.

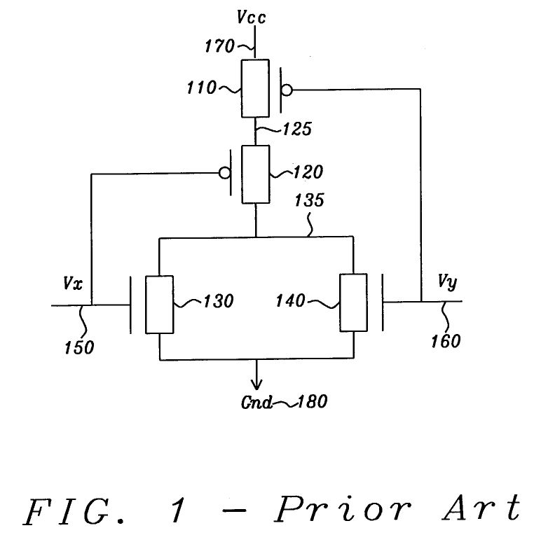

### DETAILED DESCRIPTION OF THE INVENTION

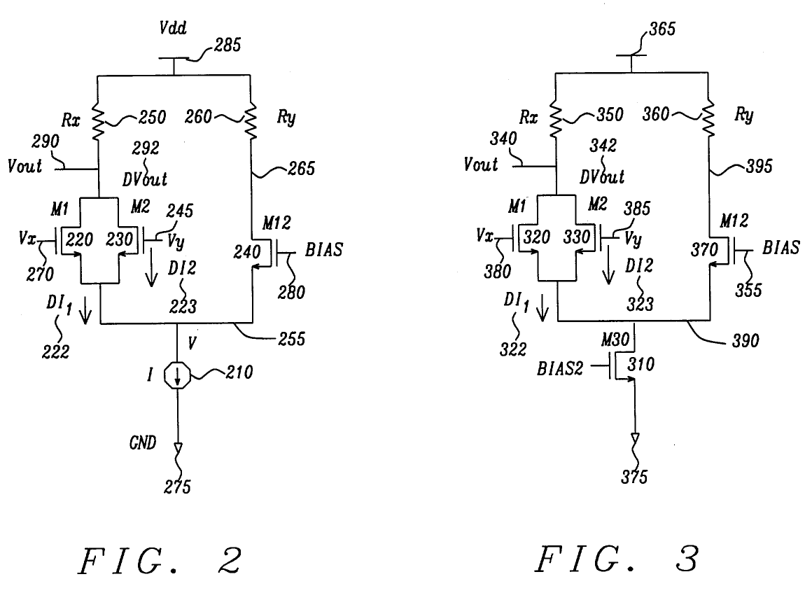

FIG. 2 shows a general schematic of the invention. A general current source 210 is shown delivering a constant current I. The current source is shown connected to ground 275 and to an internal node A 255. The two logic input signals Vx 270 and Vy 245 are shown. Signal Vx 270 goes into the gate of NMOS FET 220. Signal Vy 245 goes into the gate of NMOS FET 230. The two NMOS FETs are connected in parallel with their drains 290 connected to an internal node B 290 and their sources 255 connected in common at internal node A. The output node 290 is the drain of the two input FETs 220, 230. A resistor Rx 250 is connected between the output Vout 290 (internal node B) and the supply voltage Vdd 285.

A bias NMOS FET 240 is connected in a circuit branch parallel to the circuit branch which contains the input FETs 220, 230. The bias NMOS FET 240 is connected between node 255 (internal node A) and node 265 (internal node C). The gate of the bias FET 280 is attached to a bias voltage, BIAS 280. The drain of the bias FET 265 is connected to a resistor Ry 260. The resistor Ry 260 is connected between the power supply voltage Vdd 285 and node 265 (internal node C). The two parallel circuit branches operate like a differential amplifier. Small current differences through resistor Rx 250 caused by logical changes at the gate of FET 220 via Vx and/or the gate of FET 230 via Vy are differentially amplified to produce the correct logic level at Vout 290. This is illustrated with the four equations below. The circuit shown in FIG. 2 is able to operate at high switching speeds with low power dissipation since only small signal changes such as DI1 222 and DI2 223 shown are required to produce a logical output Vout 290, via the small change DVout 292.

In summary, the logical voltage changes a Vx 270 and Vy 245 produce small current changes DI1 222 or DI2. These small current changes through devices M1 220 and/or M2 230 result in equivalent changes in current flow through resistor Rx 250. This current change through Rx results in a DVout 292.

The transconductances of NMOS M1 and M2 220, 230 are gm1 and gm2 respectively. DI1 is the small signal drain-to-source current in M1 220. DI2 is the small signal drain-to-source current of M2 230. The variation of output voltage Dvout is equal to −(DI1+DI2)Rx. The following equations apply.

DI1=gm1(DVx−V) (1)

DI2=gm2(DVy−V) (2)

DVout=DI1Rx−DI2Rx (3)

DVout=−gm1(DVx−V)Rx−gm2(DVy−V)Ry (4)

A voltage level VLevel is chosen. If a voltage greater than VLevel is determined as Logic High, and a voltage smaller than Vlevel is determined as Logic Low, two states of Logic High and Logic Low can be derived as follows.

VHigh→Vout+DVout>VLevel

VLow→Vout+DVout<Vlevel

FIG. 3 shows a more detailed schematic for this invention. An NMOS FET M30 310 current source is shown delivering a constant current I. This is accomplished by driving the gate of the NMOS FET 310 with a BIAS2 voltage. The BIAS2 voltage is chosen so as to operate FET M30 310 in its saturation region. The FET saturation region allows the FET to act as a constant current source.

The two logical input signals Vx 380 and Vy 330 are shown. Signal Vx 380 goes into the gate of NMOS FET 320. Signal Vy goes into the gate of NMOS FET 330. The two NMOS FETs are connected in parallel with their drains 340 and sources 390 connected in common. The output node 340 is the drain of the two input FETs 320, 330. A resistor Rx 350 is connected between the output Vout 340 and the supply voltage Vdd 395.

A bias NMOS FET 370 is connected in a circuit branch parallel to the circuit branch which contains the input FETs 320, 330. The bias NMOS FET 370 is connected between node 390 and node 395. The gate of the bias FET 370 is attached to a bias voltage, BIAS 355. The drain of the bias FET 395 is connected to a resistor Ry 360. The resistor Ry 360 is connected between the power supply voltage Vdd 365 and node 395. The two parallel circuit branches operate like a differential amplifier. Small current differences through resistor Rx 350 caused by logical changes at the gate of FET 320 via Vx and/or the gate of FET 330 via Vy are differentially amplified to produce the correct logic level at Vout 340. This is illustrated with the four equations below. The circuit shown in FIG. 3 is able to operate at high switching speeds with low power dissipation since only small signal changes such as DI1 322 and DI2 323 shown are required to produce a logical output Vout 340, via the small change DVout 342.

In summary, the logical voltage changes a Vx 380 and Vy 385 produce small current changes DI1 322 or DI2 323. These small current changes through devices M1 320 and/or M2 330 result in equivalent changes in current flow through resistor Rx 350. This current change through Rx results in a DVout 342.

The transconductances of NMOS M1 and M2 320, 330 are gm1 and gm2 respectively. DI1 is the small signal drain-to-source current in M1 320. DI2 is the small signal drain-to-source current of M2 330. The variation of output voltage Dvout is equal to −(DI1+DI2)Rx. The following equations apply.

DI1=gm1(DVx−V) (1)

DI2=gm2(DVy−V) (2)

DVout=DI1Rx−DI2Rx (3)

DVout=−gm1(DVx−V)Rx−gm2(DVy−V)Ry (4)

A voltage level VLevel is chosen. If a voltage greater than Vlevel is determined as Logic High, and a voltage smaller than Vlevel is determined as Logic Low, two states of Logic High and Logic Low can be derived as follows.

VHigh→Vout+DVout>VLevel

VLow→Vout+DVout<Vle

This invention has the advantage of high speed and low power dissipation since the logical operations are performed based on small signal changes to the logical inputs. Small signal changes suggest that the waveforms do not need to traverse large voltage swings in order to determine the logical output of the logical NOR circuit of this invention. This allows the signal to switch faster, since the signals do not require time to traverse large swings. In addition, small traversal of signals implies less charging of capacitors and therefore less power dissipation.

While this invention has been particularly shown and described with Reference to the preferred embodiments thereof, it will be understood by those Skilled in the art that various changes in form and details may be made without Departing from the spirit and scope of this invention.

What is claimed is:

1. A high speed, low power complementary metal oxide semiconductor CMOS current mode NOR circuit comprising:
a current source connected between a first internal node and ground,
a pair of field effect transistors FETs connected in parallel with common source and drain terminals between a second internal node said first internal node,
a bias FET connected in a circuit branch parallel to said parallel pair of FETs and between said first internal node and a third internal node,
a first load resistor connected between said second internal node and the power supply voltage and,
a second load resistor connected between said third internal node and the power supply voltage.

2. The high speed, low power complementary metal oxide semiconductor CMOS current mode NOR circuit of claim 1 wherein said first load resistor is connected between said second internal node and the power supply voltage.

3. The high speed, low power complementary metal oxide semiconductor CMOS current mode NOR circuit of claim 1 wherein said second load resistor is connected between said third internal node and the power supply voltage.

4. The high speed, low power complementary metal oxide semiconductor CMOS current mode NOR circuit of claim 1 wherein said current source is implemented using an FET.

5. The high speed, low power complementary metal oxide semiconductor CMOS current mode NOR circuit of claim 4 wherein said current source FET has a bias voltage on its gate terminal.

6. The high speed, low power complementary metal oxide semiconductor CMOS current mode NOR circuit of claim 5 wherein said bias voltage is specified to operate said current source FET in saturation mode, which delivers constant current.

7. The high speed, low power complementary metal oxide semiconductor CMOS current mode NOR circuit of claim 1 wherein said differential pair of FETs each have unique logic signals driving their gate terminals.

8. The high speed, low power complementary metal oxide semiconductor CMOS current mode NOR circuit of claim 7 wherein said logic signals represent one of two respective logic states.

9. The high speed, low power complementary metal oxide semiconductor CMOS current mode NOR circuit of claim 8 wherein said logic signals represent the two logic states of V_high and V_low.

10. The high speed, low power complementary metal oxide semiconductor CMOS current mode NOR circuit of claim 9 wherein a voltage level, V_level is chosen whereby a voltage greater than V_level is defined to be V_high.

11. The high speed, low power complementary metal oxide semiconductor CMOS current mode NOR circuit of claim 10 wherein a voltage level, V_level is chosen whereby a voltage less than V_level is defined to be V_low.

12. The high speed, low power complementary metal oxide semiconductor CMOS current mode NOR circuit of claim 1 wherein said a bias FET connected between said first internal node and said third internal node has a bias voltage specified for its gate terminal.

13. The high speed, low power complementary metal oxide semiconductor CMOS current mode NOR circuit of claim 8 wherein said bias voltage applied to said bias FET gate terminal is specified to make said NOR circuit operate like a differential amplifier.

14. The high speed, low power complementary metal oxide semiconductor MOS current mode NOR circuit of claim 13 wherein said differential amplifier works by magnifying small signal changes caused by the logic of the voltage signals applied to said parallel FETs to result in a logical output voltage which is calibrated to represent a logical ‘1’ or logical ‘0’.

15. The high speed, low power complementary metal oxide semiconductor CMOS current mode NOR circuit of claim 1 wherein said first load resistor connected between said second internal node and the power supply voltage is specified to magnify small signal changes caused by the logic of the voltage signals applied to said parallel FETs to result in a logical output voltage which is calibrated to represent a logical ‘1’ or logical ‘0’.

16. The high speed, low power complementary metal oxide semiconductor CMOS current mode NOR circuit of claim 1 wherein said second load resistor connected between said third internal node and the power supply voltage is specified to provide for a constant bias current which is used as a known level to allow the differences in said parallel circuit branch at said second internal node to be used to discern a logical ‘1’ and a logical ‘0’.

17. A method of providing a high speed CMOS NOR circuit comprising the steps of:
sourcing current between a first internal node and ground,
connecting a pair of field effect transistors FETs in parallel with common source and drain terminals between a second internal node and said first internal node.
connecting a bias FET in a circuit branch parallel to said parallel pair of FETs and between said first internal node and said third internal node.

18. The method of providing a high speed CMOS NOR circuit of claim 17 wherein a first load resistor is connected between said second internal node and the power supply voltage.

19. The method of providing a high speed CMOS NOR circuit of claim 17 wherein a second load resistor is connected between said third internal node and the power supply voltage.

20. The method of providing a high speed CMOS NOR circuit of claim 17 wherein said current source is implemented using an FET.

21. The method of providing a high speed CMOS NOR circuit of claim 17 wherein said current source FET has a bias voltage on its gate terminal.

22. The method of providing a high speed CMOS NOR circuit of claim 17 wherein said bias voltage is specified to operate said current source FET in saturation mode, which delivers constant current.

23. The method of providing a high speed CMOS NOR circuit of claim 17 wherein said differential pair of FETs each have unique logic signals driving their gate terminals.

24. The method of providing a high speed CMOS NOR circuit of claim 17 wherein said logic signals represent one of two respective logic states.

25. The method of providing a high speed CMOS NOR circuit of claim 17 wherein said logic signals represent the two logic states of V_high and V_low.

26. The method of providing a high speed CMOS NOR circuit of claim 17 wherein a voltage level, V_level is chosen whereby a voltage greater than V_level is defined to be V_high.

27. The method of providing a high speed CMOS NOR circuit of claim 17 wherein a voltage level, V_level is chosen whereby a voltage less than V_level is defined to be V_low.
